(19) United States
(12) Patent Application Publication
(10) Pub. No.: US 2009/0186446 A1
(43) Pub. Date: Jul. 23, 2009

(54) Semiconductor device packages and methods of fabricating the same

(75) Inventors: Yong-Chai Kwon, Suwon-si (KR); Nam-Seog Kim, Yongin-si (KR); Keum-Hee Ma, Gyeongsangbuk-do (KR); Ho-Jin Lee, Seoul (KR)

Correspondence Address: MILLS & ONELLO LLP, ELEVEN BEACON STREET, SUITE 605, BOSTON, MA, 02108, US

(73) Assignee: Samsung Electronics Co., Ltd., Gyeonggi-do (KR)

(21) Appl. No.: 12/313,980

(22) Filed: Nov. 26, 2008

(30) Foreign Application Priority Data
Nov. 29, 2007 (KR) 10-2007-0123003

(51) Int. Cl. H01L 21/50

(52) U.S. Cl. 438/107; 257/E21.499

(57) ABSTRACT

Provided are semiconductor device packages and methods for fabricating the same. In some embodiments, the method includes providing a semiconductor chip on a substrate with through electrodes formed in the substrate, and providing a capping layer on the substrate to receive the semiconductor chip in a recess formed in the capping layer. The capping layer is coupled to the substrate by a bonding layer formed on the substrate, and the capping layer covers the semiconductor chip provided on the substrate. The processing of the substrate and the capping layer can be separately performed, thus allowing the material for the capping layer and/or the substrate to be selected to reduce (e.g., to minimize) a difference between the thermal expansion coefficients of the capping layer material and the substrate material.

### CROSS-REFERENCE TO RELATED APPLICATION

This U.S. non-provisional patent application claims priority under 35 U.S.C. § 119 to Korean Patent Application No. 10-2007-0123003, filed on Nov. 29, 2007, the entire contents of which are hereby incorporated by reference.

### BACKGROUND

In packaging technology for integrated circuits, the semiconductor industry continuously researches ways to miniaturize semiconductor device packages and improve semiconductor device reliability.

Diverse technologies for integrating a greater number of cells in a given area and increasing the capacities of semiconductor products are being developed. For example, stacking a plurality of cells on the surfaces of an interposer substrate to integrate a greater number of cells within a given area can yield improvements in semiconductor product capacity.

To protect cells formed on an interposer substrate from external elements, a capping layer may be formed on the interposer substrate. In some embodiments, a capping layer includes resin, and the capping layer is formed on an interposer substrate to cover cells. Research is being conducted on materials for a capping layer to allow the capping layer to protect cells from external elements and maintain reliability of the cells, and also on ways of forming the capping layer that are dependent on the material used.

### SUMMARY

The present invention relates to semiconductor device packages and methods of fabricating the same.

In one aspect, the present invention provides more reliable semiconductor device packages, which prevent deformation of a substrate and the exterior of a capping layer formed on the substrate.

In another aspect, the present invention also provides methods for fabricating more reliable semiconductor device packages, which prevent deformation of a substrate and the exterior of a capping layer formed on the substrate.

Embodiments of the present invention provide semiconductor device packages including a substrate defining via holes therethrough, a plurality of through electrodes in the via holes, a first semiconductor chip on the substrate and electrically connected to the through electrodes, and a capping layer on the substrate and defining a recess greater in size than the first semiconductor chip to receive the first semiconductor chip in the recess, the capping layer covering the first semiconductor chip.

In other embodiments of the present invention, methods for fabricating semiconductor device packages include preparing a substrate having a first surface, and a second surface opposite the first surface, forming through electrodes in via holes passing through an inside of the substrate, providing a first semiconductor chip on the first surface electrically connected to the through electrodes, forming a recess of a size greater than the first semiconductor chip in a capping layer, and covering the first semiconductor chip with the capping layer, by providing the capping layer on the substrate to receive the first semiconductor chip in the recess.

### BRIEF DESCRIPTION OF THE FIGURES

The accompanying figures are included to provide a further understanding of the present invention, and are incorporated in and constitute a part of this specification. The drawings illustrate exemplary embodiments of the present invention and, together with the description, serve to explain principles of the present invention. In the figures:

FIG. 1 is a sectional view of a semiconductor device package according to an embodiment of the present invention; and

FIGS. 2 to 10 are sectional views illustrating an embodiment of a method for fabricating the semiconductor package in FIG. 1.

### DETAILED DESCRIPTION OF EMBODIMENTS

Embodiments of the present invention will be described below in more detail with reference to the accompanying drawings. Objects, characteristics, and effects of the present invention will be readily apparent from the accompanying drawings and related embodiments. The present invention may, however, be embodied in different forms and should not be construed as limited to the embodiments set forth herein. Rather, these embodiments are provided so that this disclosure will be thorough and complete. Thus, the scope of the present invention shall not be interpreted as being limited by the embodiments described below. In the drawings provided to accompany the descriptions of embodiments below, elements may be simplified or exaggerated for the sake of clarity, and like reference numerals refer to like elements throughout.

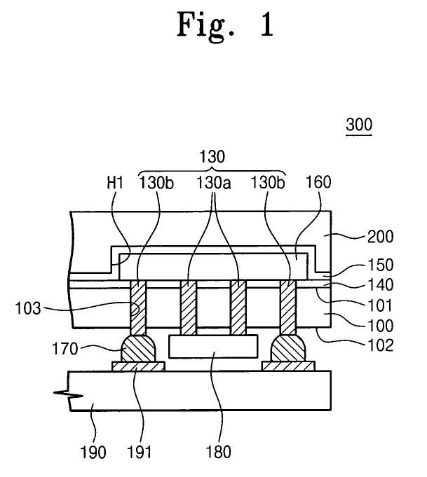

FIG. 1 is a sectional view of a semiconductor device package according to an embodiment of the present invention.

Referring to FIG. 1, a semiconductor device package 300 includes an interposer substrate 100, a capping layer 200, a first upper semiconductor chip 160, a first lower semiconductor chip 180, through electrodes 130, and a first printed circuit board (PCB) 190.

The interposer substrate 100 includes silicon and has a plate configuration. While the interposer substrate 100 includes silicon in embodiments of the present invention, the interposer substrate 100 may include ceramic or polymers.

A plurality of via holes 103 is formed in the interposer substrate 100, and the through electrodes 130 are housed within the via holes 103. Two end portions opposite each other of each of the through electrode 130 may project from an upper surface 101 and a lower surface 102 of the interposer substrate. The through electrodes 130 include a conductive material, such as copper (Cu), aluminum (Al), a copper-aluminum alloy, or a superconducting material.

A first bonding layer 140 is provided on the upper surface 101. The first bonding layer 140 may include a resin such as a polyamide or an epoxy, and the first bonding layer 140 is provided so as not to cover the upper surfaces of the through electrodes 130.

The first upper semiconductor chip 160 is provided on the first bonding layer 140 to couple to the interposer substrate 100, and the first upper semiconductor chip 160 is electrically connected to the through electrodes 130. While not illustrated in the present drawing, terminals may be provided at the lower portion of the first upper semiconductor chip 160, and the terminals may contact the through electrodes 130 to electrically connect the first upper semiconductor chip 160 to the through electrodes 130.

The first upper semiconductor chip 160 may be a memory device, a processing device such as a central processing unit (CPU), or a device having other functions. The first upper semiconductor chip 160 may be formed of a single semiconductor device, or of a plurality of stacked semiconductor devices.

The capping layer 200 for covering the first upper semiconductor chip 160 is provided on the interposer substrate 100. The capping layer 200 defines a first recess H1 that is either the same size as or larger than the first upper semiconductor chip 160. The capping layer 200 may be coupled to the interposer substrate 100 through a second bonding layer 150 covering the first upper semiconductor chip 160.

The second bonding layer 150 may be formed of an adhesive tape or a resin. If the second bonding layer 150 is formed of an adhesive tape, the adhesive tape may be a tape including low temperature co-fired ceramics (LTCC) or an adhesive tape including other ingredients. In particular, if the interposer substrate 100 includes silicon or ceramic, the second bonding layer 150 may be formed of an adhesive tape or a resin.

The capping layer 200 includes silicon. Because silicon has a higher heat transfer coefficient than many polymers, the capping layer 200 including silicon can easily dissipate heat from the first upper semiconductor chip 160 to the outside environment. Also, because silicon has better moisture absorption resistance than many polymers, the capping layer 200 including silicon is able to effectively prevent infiltration of external moisture to the first upper semiconductor chip 160, so reliability of the first upper semiconductor chip 160 can be improved.

When the capping layer 200 includes silicon like the interposer substrate 100, the capping layer 200 may expand or contract at the same rate as the interposer substrate 100. Accordingly, when the capping layer 200 and the interposer substrate 100 are coupled with the first bonding layer 140 and the second bonding layer 150, warpage of the capping layer 200 or the interposer substrate 100 from a difference between the thermal expansion coefficient of the capping layer 200 and the thermal expansion coefficient of the interposer substrate 100 can be prevented.

In embodiments of the present invention, as described above, the capping layer 200 may be formed of silicon, in order to include the same material as the interposer substrate 100. However, if the interposer substrate 100 is formed of ceramic, the capping layer 200 may also be formed of ceramic. Further, if the interposer substrate 100 is formed of a polymer, the capping layer 200 may also be formed of a polymer.

However, even if the capping layer 200 does not include the same material as the interposer substrate 100, the capping layer 200 may be formed of a material having a similar thermal expansion coefficient to that of the interposer substrate 100. When the capping layer 200 is formed of a material with a similar thermal expansion coefficient to that of the interposer substrate 100, the material may be selected such that the capping layer 200 or the interposer substrate 100 does not warp due to a difference in the thermal expansion coefficients of materials of the capping layer 200 and the interposer substrate 100.

At least one of the through electrodes 130 is electrically connected to the first lower semiconductor chip 180. In further detail, the through electrodes 130 may be divided into first through electrodes 130a and second through electrodes 130b, with the first through electrodes 130a electrically connected to the first lower semiconductor chip 180. Thus, the first upper semiconductor chip 160 is electrically connected to the first lower semiconductor chip 180 through the first through electrodes 130a.

The first lower semiconductor chip 180 may be a memory device, a processing device such as a CPU, or a device having other functions. Also, the first lower semiconductor chip 180 may be formed of a single semiconductor device, or a plurality of stacked semiconductor devices.

The first PCB 190 is electrically connected through the second through electrodes 130b to the first upper semiconductor chip 160. Specifically, the first PCB 190 includes first bumps 191, and a solder ball 170 provided for each first bump 191. The solder balls 170 are bonded to ends at one side of the second through electrodes 130b.

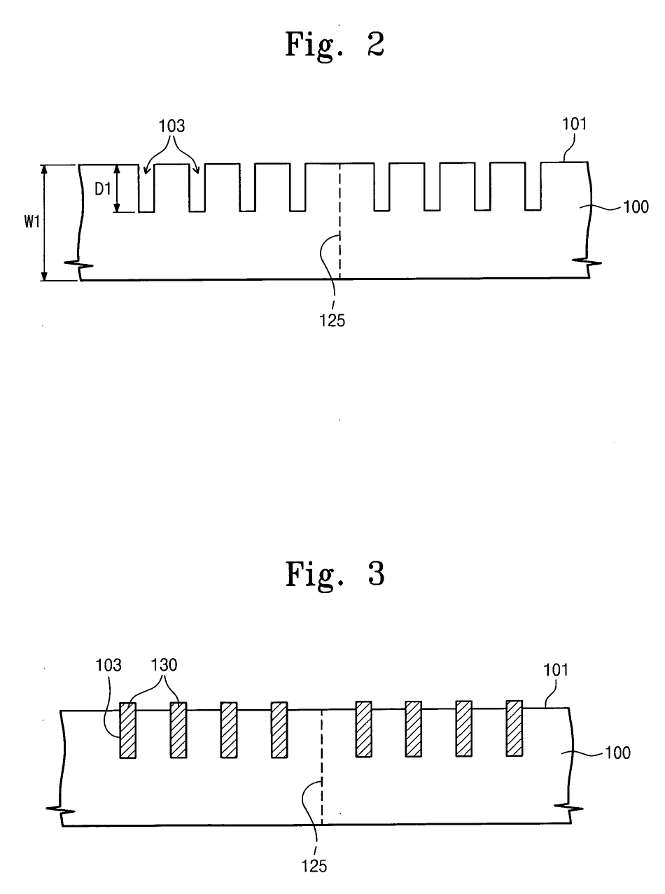

FIGS. 2 to 10 are sectional views illustrating an embodiment of a method for fabricating the semiconductor package in FIG. 1. In the description referring to FIGS. 2 to 10, elements described above are designated with like reference numerals, and repetitive description of these elements will not be provided.

Referring to FIG. 2, an interposer substrate 100 defining via holes 103 is provided. The interposer substrate 100 may be formed, for example, of silicon, and the interposer substrate 100 is configured in a plate shape with a first thickness (W1). The interposer substrate 100 has a cutting region 125 defined therein, and the interposer substrate 100 is cut along the cutting region 125 after all processing has been performed on the interposer substrate 100.

To describe the process of forming the via holes 103 in the interposer substrate 100 in detail, a mask pattern (not shown) is formed on the upper surface 101 of the interposer substrate 100, and the via holes 103 are formed by etching the interposer substrate 100 using the mask pattern. When the interposer substrate 100 is etched, the interposer substrate 100 is etched from the upper surface 101 to a first depth (D1) that is less than the first thickness (W1).

Referring to FIG. 3, the through electrodes 130 are formed by filling the via holes 103 with a conductive material. In further detail, the conductive material is provided on the interposer substrate 100 to fill the via holes 103 with the conductive material, after which the conductive material is etched to expose the interposer substrate 100, and the interposer substrate 100 may then be recessed to project the conductive material filled in the via holes 103.

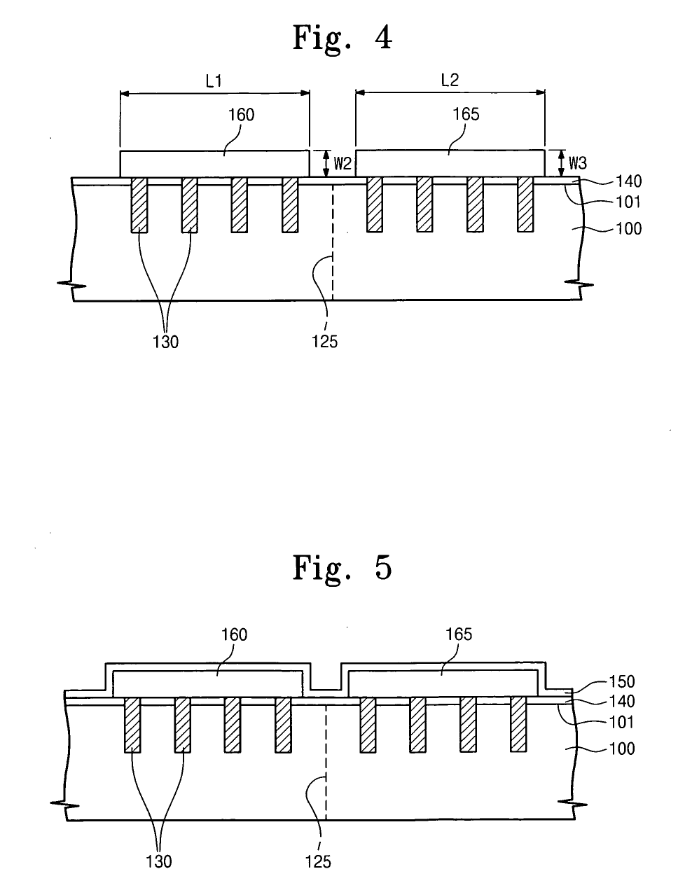

Referring to FIG. 4, a first bonding layer 140 is formed on the interposer substrate 100, and a first upper semiconductor chip 160 having a first length (L1) and a second thickness (W2), and a second upper semiconductor chip 165 having a second length (L2) and a third thickness (W3) are provided on the interposer substrate 100. The first length (L1) and the second length (L2) may be equal or different, and the second thickness (W2) and the third thickness (W3) may be equal or different. Also, while not shown in the drawings, the first upper semiconductor chip 160 and the second upper semiconductor chip 165 may have widths that are the same or different.

The first upper semiconductor chip 160 and the second upper semiconductor chip 165 are coupled to the interposer substrate 100 through the first bonding layer 140. Also, the first upper semiconductor chip 160 and the second upper semiconductor chip 165 are electrically connected to the through electrodes 130.

Referring to FIG. 5, a second bonding layer 150 is formed on the interposer substrate 100 provided with the first upper semiconductor chip 160 and the second upper semiconductor chip 165. The second bonding layer 150 may be formed by providing a tape including low temperature co-fired ceramics (LTCC) or an adhesive tape formed of other ingredients. The second bonding layer 150 may be formed by providing a resin with adhesiveness and using a spin coating technique performed on the interposer substrate 100. The above-described methods of forming the second bonding layer 150, in addition to being employable when the interposer substrate 100 includes silicon as in embodiments of the present invention, may also be employed when the interposer substrate 100 includes ceramic.

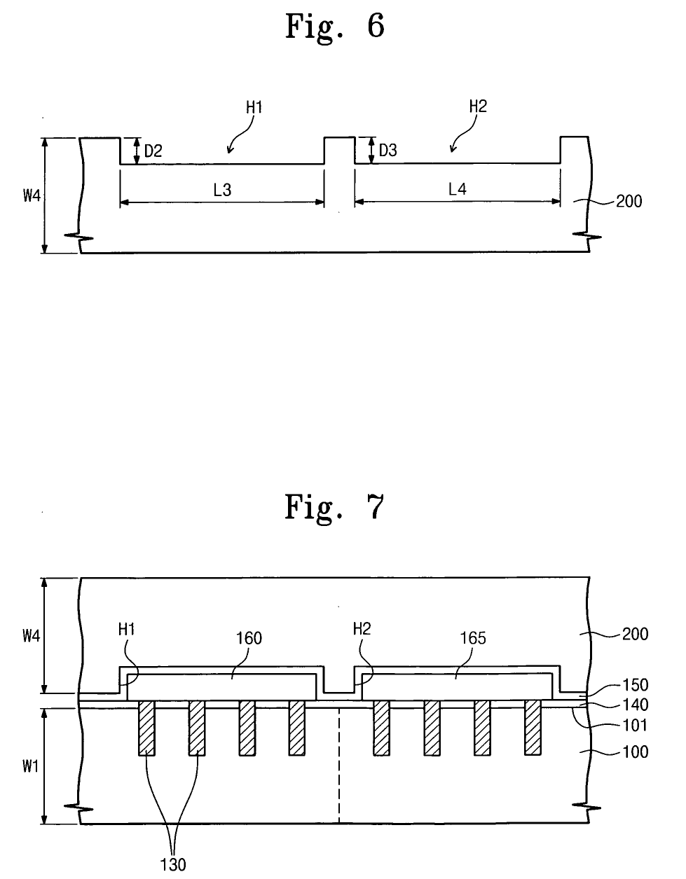

Referring to FIG. 6, the capping layer 200 having a fourth width (W4) is selectively etched to form a first recess (H1) and a second recess (H2) in the capping layer 200. In more detail, a mask pattern (not shown) may be formed on the capping layer 200 to selectively expose the capping layer 200, and the exposed capping layer may be etched to form the first recess (H1) and the second recess (H2). The first recess (H1) is defined to have a third length (L3) and a second depth (D2), and the second recess (H2) is defined to have a fourth length (L4) and a third depth (D3).

Referring again to FIG. 4, when the first recess (H1) is formed in the capping layer 200, the first recess (H1) is formed with the third length (L3) that is greater than the first length (L1) and the second depth (D2) that is greater than the second thickness (W2). Also, when the second recess (H2) is formed in the capping layer 200, the second recess (H2) is formed at the fourth length (L4) that is greater than the second length (L2) and the third depth (D3) that is greater than the third thickness (W3). In addition, while not shown in the diagrams, the width of the first recess (H1) is greater in width than that of the first upper semiconductor chip 160, and the second recess (H2) is greater in width than that of the second upper semiconductor chip 165. Accordingly, when the capping layer 200 is provided on the interposer substrate, the first upper semiconductor chip 160 can be received in the first recess (H1), and the second semiconductor chip 165 can be received in the second recess (H2).

Referring to FIG. 7, a second bonding layer 150 is formed on the interposer substrate 100 provided with the first upper semiconductor chip 160 and the second upper semiconductor chip 165, and the second bonding layer 150 is used to couple the interposer substrate 100 and the capping layer 200. As described above, because the first recess (H1) and the second recess (H2) are formed in the capping layer 200, the capping layer 200 can provide spaces to receive the first upper semiconductor chip 160 and the second upper semiconductor chip 165.

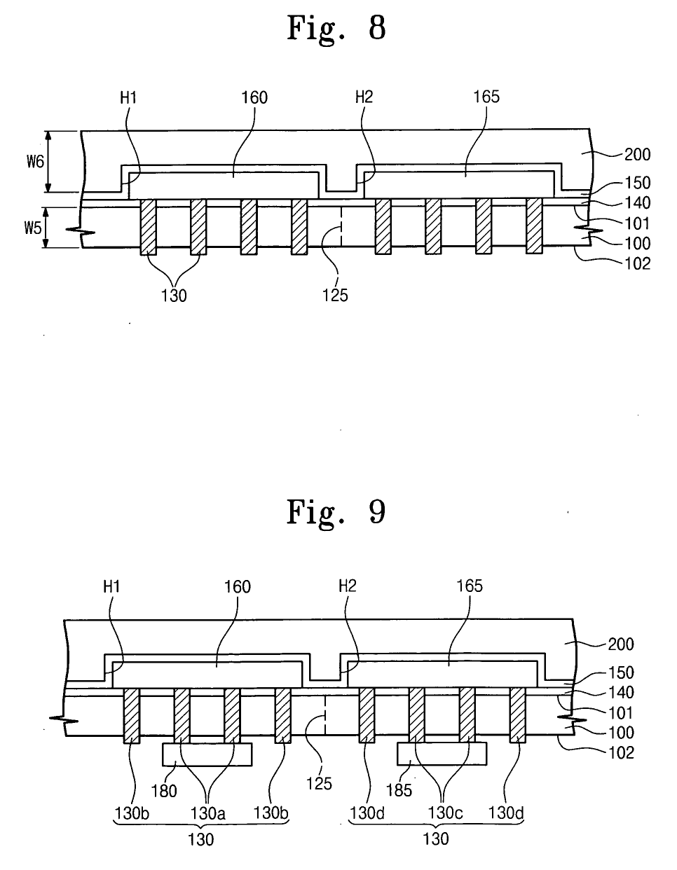

Referring to FIG. 8, the entire surfaces of the interposing substrate 100 and the capping layer 200 are etched. As a result, the thickness of the interposing substrate 100 is changed from the first thickness (W1) in FIG. 7 to a fifth thickness (W5) that is less than the first thickness (W1), and the thickness of the capping layer 200 is changed from the fourth thickness (W4) in FIG. 7 to a sixth thickness (W6). After the interposing substrate 100 is etched, the interposer substrate 100 may be recessed to project the through electrodes 130 from the lower surface 102 of the interposer substrate 100.

When the entire surfaces of the interposer substrate 100 and the capping layer 200 are etched, the capping layer 200 allows the etching of the interposer substrate 100 to be easily performed. That is, in order to etch the interposer substrate 100, a minimum thickness is required for handling the interposer substrate 100, and the capping layer 200 makes the interposer substrate 100 have at least the minimum thickness. Accordingly, the interposer substrate 100 can have a thickness below a minimum thickness, so it is easy to slim the interposer substrate 100, thus enabling the via holes 103 (shown in FIG. 2) to be formed at a shallow depth in the interposer substrate 100 and enabling the via holes to be easily formed in the interposer substrate 100.

Referring to FIG. 9, a first lower semiconductor chip 180 and a second lower semiconductor chip 185 respectively are provided to couple to the through electrodes (130) adjacent to the lower surface of the interposer substrate (100) opposite to the upper surface of the interposer substrate (100). The first lower semiconductor chip 180 and the second lower semiconductor chip 185 may be a memory device, a processing device, or a device having other functions. Also, the first lower semiconductor chip 180 and the second lower semiconductor chip 185 may be provided as a single device, or a plurality of devices in a stacked configuration.

The first lower semiconductor chip 180 and the second lower semiconductor chip 185 are electrically connected to at least one of the through electrodes 130. Specifically, the first through-electrodes 130a are electrically connected to the first lower semiconductor chip 180, and third through electrodes 130c are electrically connected to the second lower semiconductor chip 185.

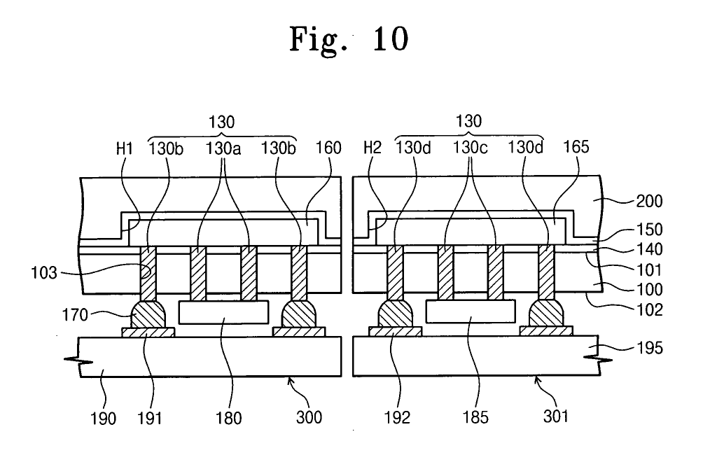

Referring to FIG. 10, a first PCB 190 and a second PCB 195 are electrically connected to at least one of the through electrodes 130. The first PCB 190 and the second PCB 195 are respectively provided with first bumps 191 and second bumps 192, and solder balls 170 are provided on the first bumps 191 and the second bumps 192. The solder balls 170 are electrically connected to at least one of the through electrodes 130. Specifically, the second through electrodes 130b are electrically connected to the first PCB 190 through solder balls formed on the first bumps 191, and as a result, the first PCB 190 is electrically connected to the first upper semiconductor chip 160. Also, fourth through electrodes 130d are electrically connected to the second PCB 195 through solder balls 170 formed on the second bumps 192, and as a result, the second PCB 195 is electrically connected to the second upper semiconductor chip 165.

After the first PCB 190 and the second PCB 195 that are electrically connected to at least one of the through electrodes 130 are provided, the interposer substrate 100 and the capping layer 200 are cut along the cutting line 125 (shown in FIG. 9). As a result, a first semiconductor device package 300, including the first upper semiconductor chip 160, the first lower semiconductor chip 180, and the first PCB 190, is completed, and a second semiconductor device package 301, including the second upper semiconductor chip 165, the second lower semiconductor chip 185, and the second PCB 195, is completed.

In the semiconductor device packages and the methods for fabricating the same described herein, after a substrate and a capping layer are separately processed, the capping layer and substrate are coupled. Accordingly, the material for the capping layer can be selected to reduce or to minimize a difference in the thermal expansion coefficients of the capping layer material and the substrate material, and to prevent warpage of the substrate or the capping layer from an effective difference between thermal expansion coefficients of the capping layer material and the substrate material.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

1-10. (canceled)

11. A method for fabricating a semiconductor device package, the method comprising:
preparing a substrate comprising a first surface, and a second surface opposite the first surface;
forming through electrodes in via holes passing through an inside of the substrate;
providing a first semiconductor chip on the first surface and electrically connected to the through electrodes;
forming a recess of a size greater than the first semiconductor chip in a capping layer; and
covering the first semiconductor chip with the capping layer by providing the capping layer on the substrate to receive the first semiconductor chip in the recess.

12. The method of claim 11, further comprising:
projecting the through electrodes from the second surface by etching the substrate after providing the capping layer on the substrate; and
providing a second semiconductor chip electrically connected to at least one of the projected through electrodes.

13. The method of claim 11, wherein the substrate and the capping layer comprise a material that is the same.

14. The method of claim 11, wherein the substrate and the capping layer have substantially same thermal expansion coefficients.

15. The method of claim 11, wherein the substrate and the capping layer comprise at least one of silicon, a ceramic, and a polymer.

16. The method of claim 11, further comprising forming a bonding layer on the first semiconductor chip to couple the capping layer to the substrate and the first semiconductor chip.

17. The method of claim 16, wherein the capping layer comprises at least one of a silicon or a ceramic material, and the bonding layer is one of an adhesive tape, a resin layer, and a tape comprising low temperature co-fired ceramics.

18. The method of claim 11, further comprising providing a printed circuit board separated from the first semiconductor chip by the substrate, and electrically connected to the first semiconductor chip through at least one of the through electrodes.

19. The method of claim 18, wherein the printed circuit board is electrically connected to the first semiconductor chip through a bump or a solder ball.

20. The method of claim 11, wherein
the first semiconductor chip has a first thickness, a first width, and a first length, and
the recess has a second thickness greater than the first thickness, a second width greater than the first width, and a second length greater than the first length.
